(19) United States
(12) Patent Application Publication
(10) Pub. No.: US 2025/0337450 A1
(43) Pub. Date: Oct. 30, 2025

(54) MOBILE PHONE PROTECTIVE CASE STRUCTURE

(71) Applicant: Chia-Hao Lin, New Taipei City (TW)

(72) Inventor: Chia-Hao Lin, New Taipei City (TW)

(21) Appl. No.: 18/789,611

(22) Filed: Jul. 30, 2024

(30) Foreign Application Priority Data
Apr. 26, 2024 (TW) 113204261

(51) Int. Cl. H04B 1/3888; H03K 17/96

(52) U.S. Cl. CPC H04B 1/3888; H03K 17/962

(57) ABSTRACT

A mobile phone protective case structure includes a protective case and a sensor button. The protective case has a circumferential frame and an accommodation space within the frame for accommodating a mobile phone having at least one touch button. The protective case has a button positioning hole corresponding in position to the touch button. The sensor button is disposed in the button positioning hole, and includes an outer frame, an elastic ring, and a sensing conductive module. The outer frame has a through hole. The outer edge of the elastic ring is attached to the outer frame, and the inner edge of the elastic ring is attached to the sensing conductive module. The sensing conductive module is exposed through the through hole of the outer frame. The outer frame is secured to the protective case, and the sensing conductive module corresponds to the touch button.

### BACKGROUND OF THE PRESENT INVENTION

### Field of Invention

The present invention relates to a mobile phone protective case structure, and more particularly to a mobile phone protective case structure having a protective case and a sensor button for touching and applying pressure to operate the functions of a mobile phone, so that the touch button of the mobile phone can be operated easily.

### Description of Related Arts

As shown in FIG. 1, in these days, a mobile phone 1 has a touch button 2 (virtual button) with pressure detection technology, instead of a normal mechanical button. The touch button 2 may be a capacitive touch button or a touch screen button. The user can customize the function of the touch button 2 and operate the touch button 2 by touching, sliding, applying pressure, etc. For example, the touch button may be a capacitive touch button that uses tactile feedback to simulate the feeling of pressing a traditional button or uses pressure sensing technology to sense the user's pressing time, strength, magnitude, and so on to trigger the operation functions of the mobile phone, such as the adjustment, switching, setting and switching functions for operation/control of the mute switch, volume control, voice recording, turning on the camera, taking photos, video recording or other quick operations, etc. People pay more attention to protect their mobile phones 1, so the users always purchase a protective case to protect their mobile phones 1. The protective case has an opening corresponding in position to the touch button 2 of the mobile phone 1. The protective case is too thick, which makes the touch button 2 deep and difficult to operate, affecting the convenience of user's finger operation. Therefore, it is the goal of the industry to improve the ease of operation of the touch button 2 in the protective case.

### SUMMARY OF THE PRESENT INVENTION

In view of the deficiencies of the prior art, the primary object of the present invention is to provide a mobile phone protective case structure. The mobile phone protective case structure comprises a protective case and a sensor button corresponding in position to a touch button of a mobile phone. The sensor button can sense the user's touch, slide and pressure and transmit the senses to the surface of the touch button, so that the mobile phone can perform actions corresponding to the senses, thereby achieving the practical effect of convenient control of the touch button on the protective case.

According to the foregoing object, the mobile phone protective case structure provided by the present invention comprises a protective case and a sensor button. The protective case has a circumferential frame and an accommodation space within the frame for accommodating a mobile phone, the mobile phone has at least one touch button. The protective case has a button positioning hole corresponding in position to the touch button. The sensor button is disposed in the button positioning hole. The sensor button includes an outer frame, an elastic ring, and a sensing conductive module. The outer frame has an outer surface, an inner surface, and a through hole passing through the outer surface and the inner surface. The outer frame is secured in the button positioning hole. The elastic ring has a flat outer ring edge, a flat inner ring edge, and a curved elastic section connected between the outer ring edge and the inner ring edge. One side of the outer ring edge, facing away from the touch button, is attached to the inner surface of the outer frame. One side of the inner ring edge, facing away from the touch button, is attached to an outer edge of the sensing conductive module. The sensing conductive module has one end extending toward the touch button. The sensing conductive module is exposed through the through hole of the outer frame. The sensor button is secured on the protective case.

In one embodiment of the present invention, an outer support ring is provided between the outer ring edge and the inner surface, and an inner support ring is provided between the inner ring edge and the sensing conductive module.

In one embodiment of the present invention, the outer support ring and the inner support ring are made of a stainless steel material.

In one embodiment of the present invention, the sensor button further includes a restricting ring. The restricting ring has an L-shaped cross-section. The restricting ring includes an axial retaining portion and a restricting portion extending radially toward a center of the restricting ring. One end of the retaining portion is attached to another side of the outer ring edge, facing away from the outer support ring. The restricting portion is connected to another end of the retaining portion, facing away from the outer ring edge. The restricting portion extends to a position corresponding to the inner ring edge.

In one embodiment of the present invention, the sensing conductive module includes a plurality of conductive portions arranged in sequence and pointing in the direction of the touch button. The conductive portions are exposed on two opposite surfaces of the sensing conductive module. Two ends the conductive portions are flush with the two opposite surfaces of the sensing conductive module.

In one embodiment of the present invention, a covering sheet is provided on one surface of the sensing conductive module.

In one embodiment of the present invention, the covering sheet is transparent, and a printing layer is provided between the sensing conductive module and the covering sheet.

In one embodiment of the present invention, the elastic ring is a made of a silicone material.

In one embodiment of the present invention, the touch button is located on an edge of the mobile phone, and the button positioning hole is defined in the frame of the protective case.

In one embodiment of the present invention, the touch button is located on a back of the mobile phone. The protective case further has a back plate. The frame surrounds the back plate. The button positioning hole is defined in the back plate of the protective case.

When the user's finger touches or applies pressure to the sensor button, the touch button receives the touch or pressure signal and the mobile phone generates the corresponding setting action and function, thereby achieving the practical effect of convenient operation.

### BRIEF DESCRIPTION OF THE DRAWINGS

FIG. 1 is a perspective view of a mobile phone having a touch button;

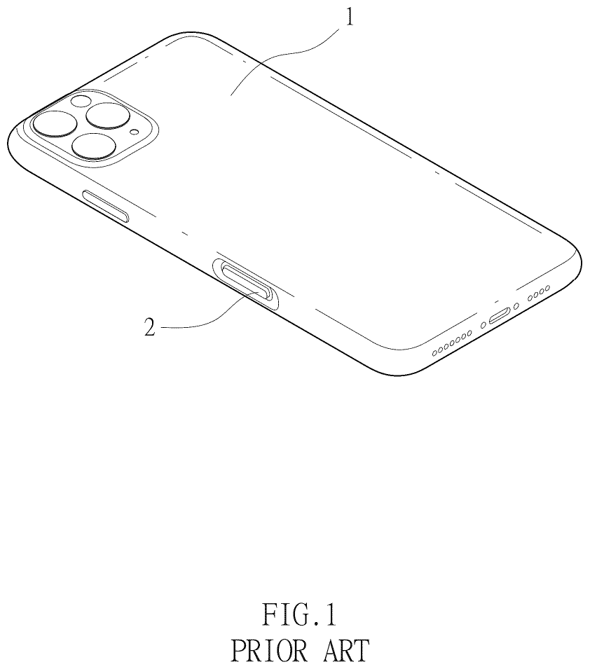

FIG. 2 is a perspective view of the present invention and the mobile phone;

FIG. 3 is an exploded view of a sensor button of the present invention;

FIG. 4 is a partial sectional view of the present invention fitted onto the mobile phone;

FIG. 5 is a schematic view of the present invention fitted onto the mobile phone when a user presses the sensor button; and

FIG. 6 is a perspective view of another embodiment of present invention and the mobile phone, wherein the sensor button is disposed on a back plate.

### DETAILED DESCRIPTION OF THE PREFERRED EMBODIMENT

Embodiments of the present invention will now be described, by way of example only, with reference to the accompanying drawings.

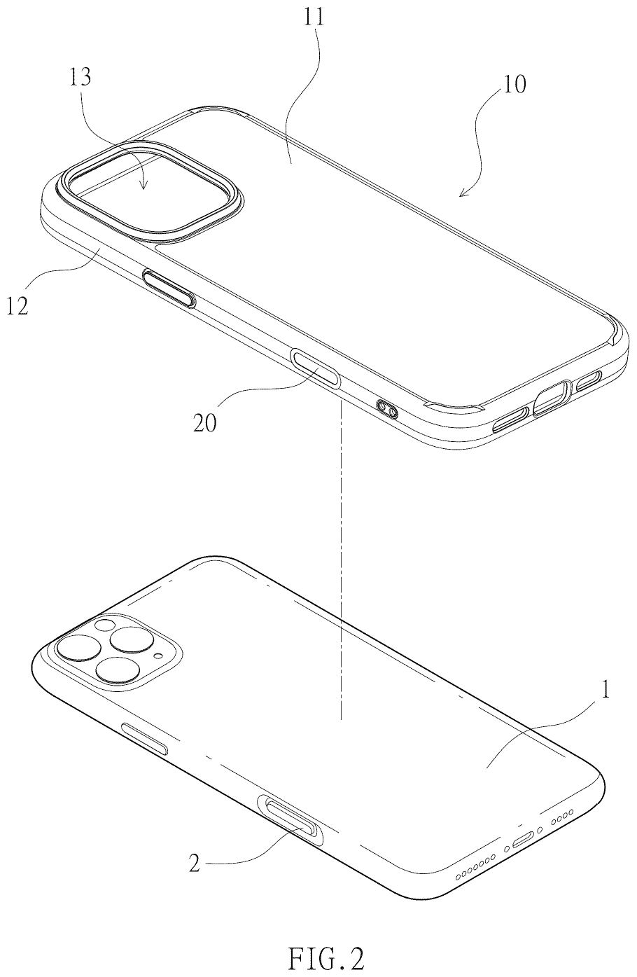

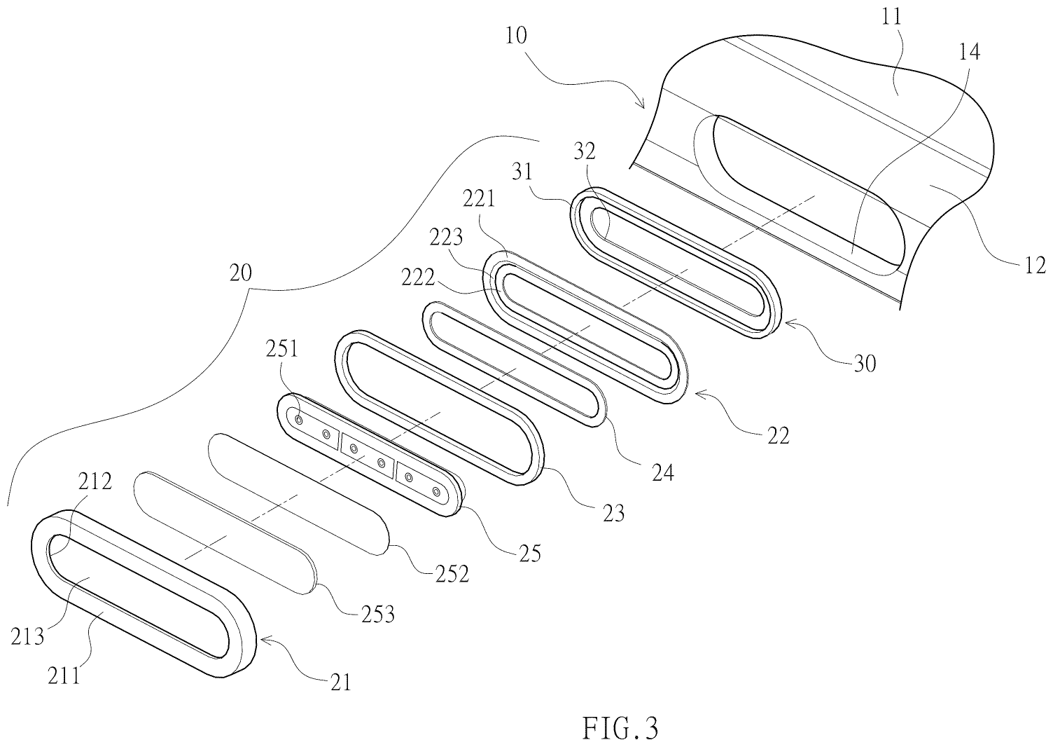

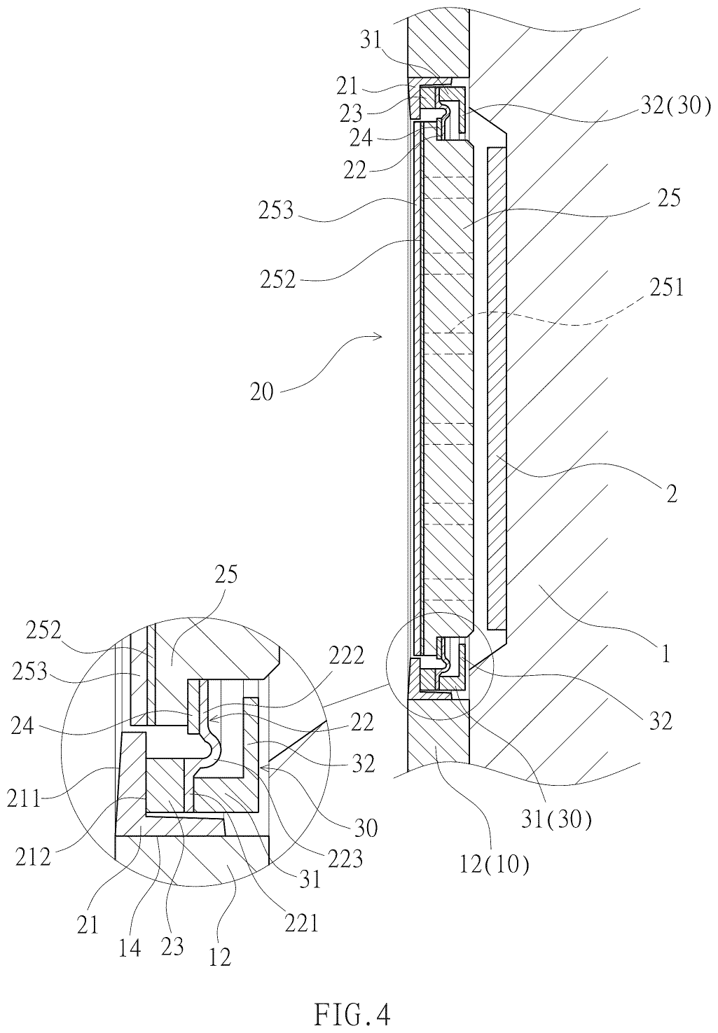

Referring to FIG. 2 through FIG. 5, the present invention discloses a mobile phone protective case structure, comprising a protective case 10 and a sensor button 20.

The protective case 10 has a back plate 11, a frame 12 surrounding the back plate 11, and an accommodation space 13 within the frame 12 for accommodating a mobile phone 1. One edge of the mobile phone 1 has a touch button 2. The frame 12 of the protective case 10 has a button positioning hole 14 corresponding in shape to the touch button 2.

The sensor button 20 is disposed in the button positioning hole 14 of the protective case 10. The sensor button 20 includes an outer frame 21, an elastic ring 22, an outer support ring 23, an inner support ring 24, a sensing conductive module 25, and a restricting ring 30. The outer frame 21 corresponds in shape to the button positioning hole 14. The outer frame 21 has an outer surface 211, an inner surface 212, and a through hole 213 passing through the outer surface 211 and the inner surface 212. The outer frame 21 is secured in the button positioning hole 14. The elastic ring 22 has a flat outer ring edge 221, a flat inner ring edge 222, and a curved elastic section 223 connected between the outer ring edge 221 and the inner ring edge 222. The outer support ring 23 corresponds in shape to the outer ring edge 221 and is attached to one side of the outer ring edge 221, facing away from the touch button 2. One side of the outer support ring 23, facing away from the outer ring edge 221, is attached to the inner surface 212 of the outer frame 21. The inner support ring 24 corresponds in shape to the inner ring edge 222, and is attached to one side of the inner ring edge 222, facing away from the touch button 2. One side of the inner support ring 24, facing away from the inner ring edge 222, is attached to the outer edge of the sensing conductive module 25. The sensing conductive module 25 has one end extending toward the touch button 2 so that the sensing conductive module 25 is in contact with the touch button 2 when in use. The sensing conductive module 25 includes a plurality of conductive portions 251 arranged in sequence and pointing in the direction of the touch button 2. The conductive portions 251 are exposed on two opposite surfaces of the sensing conductive module 25. A printing layer 252 is provided on the surface of the sensing conductive module 25, facing away from the touch button 2. A transparent covering sheet 253 is provided on the printing layer 252. The covering sheet 253 and the sensing conductive module 25 may be exposed through the through hole 213 of the outer frame 21. The restricting ring 30 has an L-shaped cross-section. The restricting ring 30 has an axial retaining portion 31 and a restricting portion 32 extending radially toward the center of the restricting ring 30. One end of the retaining portion 31 is attached to another side of the outer ring edge 221, facing away from the outer support ring 23. The restricting portion 32 is connected to another end of the retaining portion 31, facing away from the outer ring edge 221. The restricting portion 32 extends to a position corresponding to the inner ring edge 222 so that the sensor button 20 is secured on the protective case 10. When the user touches or applies pressure to the sensor button 20 with his/her finger 3, the touch button 2 will receive the touch or pressure signal and the mobile phone 1 will generate the corresponding setting action and function. In this way, the touch button 2 can be operated with ease.

The assembly, function and effect of the above embodiment are described in detail below. As shown in FIG. 2 to FIG. 5, the outer frame 21 of the present invention is made of a hard material such as metal or plastic, but not limited thereto, so as to position the sensor button 20 firmly. The elastic ring 22 is a made of a soft elastic material such as silicone, rubber and plastic, but not limited thereto, so that the elastic ring 22 may be elastically deformed by external force and recover its shape when the external force is removed. The outer support ring 23 and the inner support ring 24 are made of a hard material such as metal or plastic, but not limited thereto. Preferably, they are made of stainless steel because stainless steel is hard and not easily deformed and its thickness is relatively thinner than other materials. With the reinforcement of the outer support ring 23 and the inner support ring 24, the outer edge and the inner edge of the elastic ring 22 can be kept flat and will not be deformed. When the elastic ring 22 changes in elasticity, the pressure will be evenly distributed on the elastic ring 22, such that the sensor button 20 can be pressed smoothly to prevent the sensor button 20 from warping to cause bad touch. The printing layer 252 may be coated and printed with decorative colors, patterns, designs, lines or mesh patterns according to the user's needs, which makes the sensor button 20 more diverse. The covering sheet 253 is made of transparent materials such as sapphire, glass, plastic sheet, etc., but not limited thereto, so as to reveal the patterns and designs of the printing layer 252. The conductive portions 251 of the sensing conductive module 25 are capable of conducting the current from the finger. The conductive portions 251 are made of conductive metal materials, chemical metal composite materials or semiconductor materials, and so on, but not limited thereto. When the finger 3 touches the covering sheet 253, the touch signal will be transmitted to the conductive portions 251 through the covering sheet 253 and the printing layer 252, and the conductive portions 251 will transmit the touch signal to the touch button 2. At this time, the controller of the touch button 2 deduces the position of the finger 3 and the function according to the difference in current change. In this way, the user may apply force to press the sensor button 20 so that the sensor button 20 presses against the touch button 2. The sensor button 20 has the sensing conductive module 25 therein, which can transmit the pressure value to the touch button 2, such that the touch button 2 senses the user's pressing time, strength and magnitude to trigger the operation function.

In one embodiment of the present invention, the conductive portions 251 are spaced and arranged in a line so that they are evenly distributed on the sensing conductive module 25. When the finger 3 touches any position on the surface of the covering sheet 253, the touch signal will be transmitted to one end of at least one of the conductive portions 251. In this way, the touch signal of the finger 3 can be transmitted to the touch button 2.

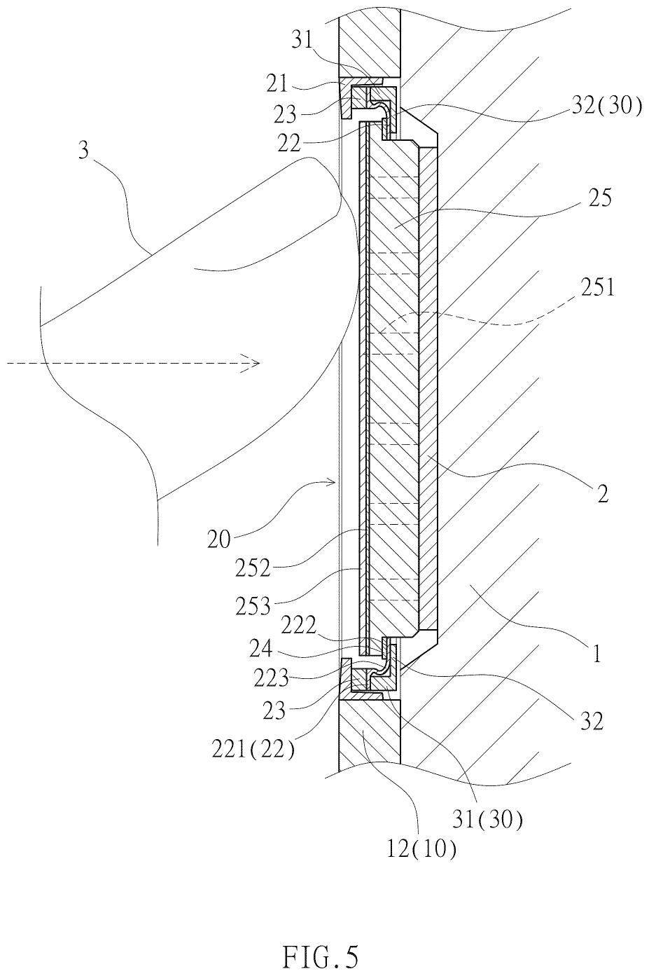

As shown in FIG. 5, when the finger 3 presses the sensor button 20 via the through hole 213, the curved elastic section 223 of the elastic ring 22 will be deformed, enabling the sensing conductive module 25 to be moved toward the touch button 2 so that one end of the sensing conductive module 25 is in contact with the touch button 2. The pressing force exerted by the finger 3 can be directly transmitted to the touch button 2 through the sensing conductive module 25. The sensing conductive module 25 is made of a non-elastically deformable material, so it can transmit the pressing force more accurately. It is easier for the user to control the pressing force, achieving the purpose of easy control. It is worth mentioning that the restricting ring 30 is made of hard materials such as plastic, but not limited thereto. When the sensing conductive module 25 is pressed, the restricting portion 32 will restrict the press stroke of the sensing conductive module 25, such that the restricting portion 32 can block the sensing conductive module 25 from moving too much and can prevent the finger 3 from pressing excessively. This prevents the surface of the touch button 2 from being be abraded or scratched as a result of a larger force applied to the touch button 2, so as to achieve the effect of protecting the touch button 2.

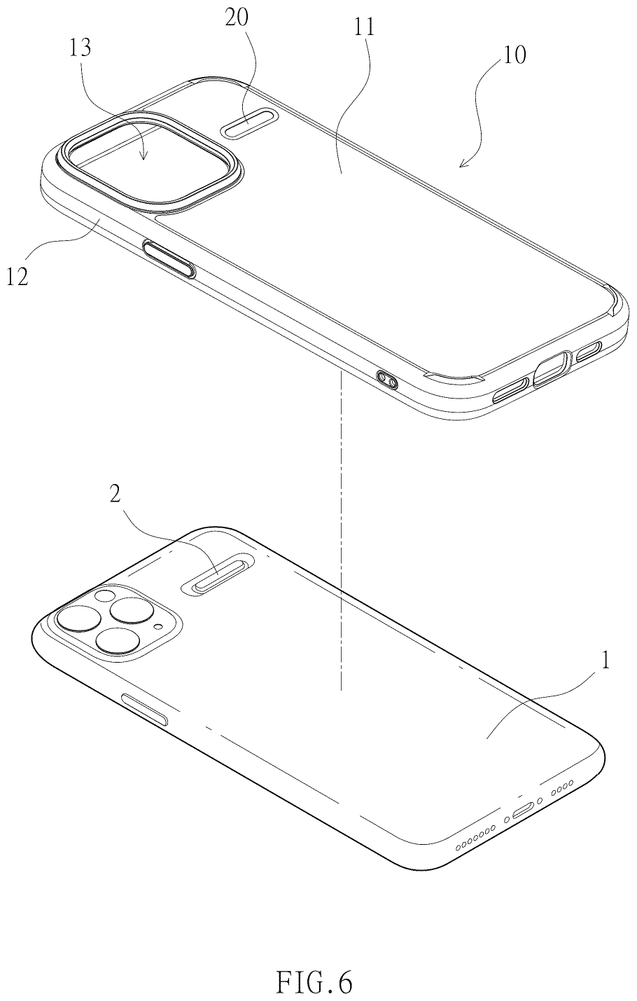

As shown in FIG. 6, if the touch button 2 is disposed on the back of the mobile phone 1 (for example, it is used to adjust the focus when the camera is turned on), the sensor button 20 may be disposed on the back plate 11 corresponding in position to the touch button 2 according to the technology of the present invention.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A mobile phone protective case structure, comprising a protective case and a sensor button;
the protective case having a circumferential frame and an accommodation space within the frame for accommodating a mobile phone, the mobile phone having at least one touch button, the protective case having a button positioning hole corresponding in position to the touch button;
the sensor button being disposed in the button positioning hole, the sensor button including an outer frame, an elastic ring, and a sensing conductive module; the outer frame having an outer surface, an inner surface, and a through hole passing through the outer surface and the inner surface, the outer frame being secured in the button positioning hole; the elastic ring having a flat outer ring edge, a flat inner ring edge, and a curved elastic section connected between the outer ring edge and the inner ring edge; one side of the outer ring edge, facing away from the touch button, being attached to the inner surface of the outer frame; one side of the inner ring edge, facing away from the touch button, being attached to an outer edge of the sensing conductive module, the sensing conductive module having one end extending toward the touch button, the sensing conductive module being exposed through the through hole of the outer frame, the sensor button being secured on the protective case.

2. The mobile phone protective case structure as claimed in claim 1, wherein an outer support ring is provided between the outer ring edge and the inner surface, and an inner support ring is provided between the inner ring edge and the sensing conductive module.

3. The mobile phone protective case structure as claimed in claim 2, wherein the outer support ring and the inner support ring are made of a stainless steel material.

4. The mobile phone protective case structure as claimed in claim 2, wherein the sensor button further includes a restricting ring, the restricting ring has an L-shaped cross-section, the restricting ring includes an axial retaining portion and a restricting portion extending radially toward a center of the restricting ring, one end of the retaining portion is attached to another side of the outer ring edge, facing away from the outer support ring; the restricting portion is connected to another end of the retaining portion, facing away from the outer ring edge, and the restricting portion extends to a position corresponding to the inner ring edge.

5. The mobile phone protective case structure as claimed in claim 1, wherein the sensing conductive module includes a plurality of conductive portions arranged in sequence and pointing in the direction of the touch button, the conductive portions are exposed on two opposite surfaces of the sensing conductive module, and two ends the conductive portions are flush with the surfaces of the sensing conductive module, respectively.

6. The mobile phone protective case structure as claimed in claim 1, wherein a covering sheet is provided on one surface of the sensing conductive module.

7. The mobile phone protective case structure as claimed in claim 6, wherein the covering sheet is transparent, and a printing layer is provided between the sensing conductive module and the covering sheet.

8. The mobile phone protective case structure as claimed in claim 1, wherein the elastic ring is a made of a silicone material.

9. The mobile phone protective case structure as claimed in claim 1, wherein the touch button is located on an edge of the mobile phone, and the button positioning hole is defined in the frame of the protective case.

10. The mobile phone protective case structure as claimed in claim 1, wherein the touch button is located on a back of the mobile phone, the protective case further has a back plate, the frame surrounds the back plate, and the button positioning hole is defined in the back plate of the protective case.
